(19) United States
(12) Patent Application Publication
(10) Pub. No.: US 2024/0186280 A1
(43) Pub. Date: Jun. 6, 2024

(54) THERMOCOMPRESSION BONDING TOOL FOR PANEL-LEVEL THERMO-COMPRESSION BONDING

(71) Applicant: Intel Corporation, Santa Clara, CA (US)

(72) Inventors: Minglu LIU, Chandler, AZ (US); Andrey GUNAWAN, Paradise Valley, AZ (US); Gang DUAN, Chandler, AZ (US); Edvin CETEGEN, Chandler, AZ (US); Yuting WANG, Chandler, AZ (US); Mine KAYA, Scottsdale, AZ (US); Kartik SRINIVASAN, Gilbert, AZ (US); Mihir OKA, Chandler, AZ (US); Anurag TRIPATHI, Gilbert, AZ (US)

(21) Appl. No.: 18/060,596

(22) Filed: Dec. 1, 2022

(51) Int. Cl. H01L 23/00

(52) U.S. Cl. CPC H01L 24/75; H01L 24/81; H01L 24/97; H01L 2224/75251; H01L 2224/75252; H01L 2224/7598; H01L 2224/75985; H01L 2224/81093; H01L 2224/81097; H01L 2224/81203; H01L 2224/81815; H01L 2224/95093; H01L 2224/97; H01L 2924/3511; H01L 2924/37001; H01L 2924/3841

(57) ABSTRACT

The present disclosure is directed to an apparatus having a bond head configured to heat and compress a semiconductor package assembly, and a bonding stage configured to hold the semiconductor package assembly, wherein the bonding stage comprises a ceramic material including silicon and either magnesium or indium.

### BACKGROUND

For integrated circuit design and fabrication, the need to improve performance and lower costs are constant challenges. Cost savings may be potentially realized by building dies on semiconductor panels rather than semiconductor wafers. By using a rectangular panel as a carrier, panel-level fan-out technology, which uses a molded embedded design, offers the potential for lower production cost due to a higher area utilization ratio of the carrier and better economical manufacturing, especially for large packages.

Presently, there are efforts to develop panel-level packaging technology that will follow a roadmap that will lead to increasingly larger panels, e.g., 500 mm by 500 mm panels and larger. However, there may be physical constraints in panel-level packaging that may hinder the use of larger panels, such as panel warpage, and the handling capability of processing tools, which may render processing operations extremely difficult to control and may result in low yields.

An important process that is used in multiple steps during semiconductor fabrication involves thermocompression bonding, which includes heating and applying thermal and mechanical pressure to join two components or bodies. The bonding tools that are used are typically fully automated, i.e., the automated loading and unloading of bond chucks/stages and the automated processing in the amount of applied heat and force on the components. It is critically important to have thermocompression bonding tools for panel-level packaging that are properly characterized and used the correct inputs for the assembly processes to achieve the chip gap heights and chip alignment as set forth in the production design.

In a thermocompression bonding (TCB) tool, a bond stage with high coefficient of thermal expansion (CTE) may induce large variations in local expansion and warpage. These large variations in local expansion and warpage may adversely impact the accuracy of chip gap height (CGH) control and thus impact process window and process yield.

Previously, modifications and optimizations have been applied on thermocompression bonding processes to solve the aforementioned issues. One previous method was to switch (e.g., from position-) to force-based control process. However, there is a limitation to force-based control process, especially for fine pitch applications (e.g., solder bump pitch <50 μm) when solder volume and force signal scale down dramatically.

Therefore, there is a need for a thermocompression bonding toll which is able to accurately control the chip gap height (CGH) during the compression process.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1 shows an exemplary representation of a thermocompression bonding tool and according to an aspect of the present disclosure;

FIG. 2 shows a simplified flow diagram for an exemplary method according to an aspect of the present disclosure; and

FIG. 3 shows a simplified flow diagram for another exemplary method according to an aspect of the present disclosure.

### DETAILED DESCRIPTION

The following detailed description refers to the accompanying drawings that show, by way of illustration, specific details, and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

A high degree of accuracy (e.g., <1 μm) in x, y, z, and theta (rotational) placements may be required for panel-level thermocompression bonding processes and chip gap height and alignment control for fine-pitch applications (bump pitch <50 μm). It is difficult to achieve a high degree of x, y, z, and theta placement accuracy with the existing thermocompression bonding tool designs due to the large form factor for panel-level tools (>500×500 mm), the elevated process temperatures (>300°) C., fast heating/cooling rate (>100 C/s), and material properties limitations (e.g., non-zero coefficient of thermal expansion (CTE), non-zero thermal conductivity, finite stiffness, etc.).

The present disclosure is directed to an apparatus including a bond head configured to heat and compress a semiconductor package assembly. The apparatus also includes a bonding stage configured to hold the semiconductor package assembly, wherein the bonding stage includes a ceramic material including silicon and either magnesium or indium.

In another aspect, the present disclosure is directed to a method providing an apparatus including a bond head configured to heat and compress a semiconductor package assembly and a bonding stage including a ceramic material including silicon and either magnesium or indium, and holding the semiconductor package assembly using the bonding stage.

In yet another aspect, the present disclosure is directed to a method providing an apparatus including a bond head configured to heat and compress a semiconductor package assembly and a bonding stage including a ceramic material including silicon and either magnesium or indium, providing the semiconductor package assembly comprising a plurality of semiconductor packages and a semiconductor panel to undergo a thermocompression bonding process, and positioning each of the plurality of semiconductor packages on the bonding stage.

In an aspect, a bond stage made of ultra-low CTE material (e.g., CTE of less than 1 ppm/K when heated up to 300° C.) will minimize thermal expansion and local warpage upon fast heating/cooling during thermocompression bonding process, which in turn reduces the chip gap height variation. This is crucial to achieve accurate dynamic chip gap control during bonding process (<1 μm accuracy), which consequently maximize process window for fine-pitch applications (solder bump pitch <50 μm).

To more readily understand and put into practical effect the present thermocompression bonding tool with chip gap height control, which may be used for panel-level manufacturing to improve yield and performance, particular aspects will now be described by way of examples provided in the drawings that are not intended as limitations. The advantages and features of the aspects herein disclosed will be apparent through reference to the following descriptions relating to the accompanying drawings. Furthermore, it is to be understood that the features of the various aspects described herein are not mutually exclusive and can exist in various combinations and permutations. For the sake of brevity, duplicate descriptions of features and properties may be omitted.

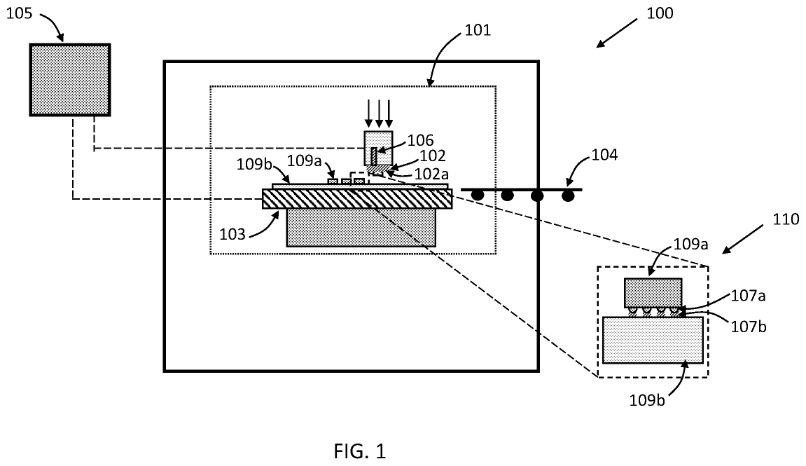

In FIG. 1, an exemplary representation of a thermocompression bonding tool 100 is shown according to an aspect of the present disclosure. The thermocompression bonding tool 100 may have a bonding module 101 with a bond head 102, which has a heating and compression surface 102a, which provides a downward compressive force to enable the thermocompression bonding, and a bonding stage or bonding chuck 103,

In an aspect, the bonding stage 103 may provide a rigid and fixed or movable surface, for receiving and supporting a semiconductor package assembly 110 during the bonding process. The bonding stage 103 may also include a heating element to facilitate the thermocompression bonding. The bonding stage 103 may include a ceramic material including silicon and either magnesium or indium. The bonding stage 103 may be a cordierite ceramic including magnesium, iron, aluminum, and silicon or a lithium-aluminosilicate glass-ceramic. The bonding stage 103 may be made of a material which has a coefficient of thermal expansion (CTE) of less than 1 ppm/K when heated up to 300° C.

In an aspect, the bond head 102 may be movable and also have a sensor 106, which may be used to measure, for example, z-direction movement and a force response from a semiconductor package 109a.

In an aspect, a transport/conveyer system 104 may be used to move the semiconductor package assembly 110 from a storage rack (not shown) onto the bonding stage 103. Alternatively, in another aspect, a handling mechanism (not shown) may be used that lifts the semiconductor package assembly 110 onto and off the bonding stage 103.

In an aspect, the thermocompression bonding tool 100 may have a controller 105 that is coupled to the bond head 102 and the bond stage 103. The controller 105 may be used to control the thermocompression process. The controller 105 may be used to obtain a displacement of the bond head 102 that results in a desired chip gap height for the semiconductor package assembly 110.

It is understood that a typical thermocompression bonding temperature profile may have several segments or cycles, including heating, dwelling, and cooling. Throughout the bonding process, both the thermocompression bonding tool and the semiconductor packages undergoing the bonding operation are experiencing expansions and contractions, which need to be accounted for if the desired chip gap height is to be attained.

In an aspect, the semiconductor package assembly 110 may include a plurality of semiconductor packages 109a and a semiconductor panel 109b.

In an aspect, the bond head 102 and the bonding stage 103 are configured to thermocompressively bond the plurality of semiconductor packages 109a onto the semiconductor panel 109b.

In an aspect, the bond head 102 is configured to reflow solder flux between the semiconductor panel 109b and the plurality of semiconductor packages 109a.

As shown in FIG. 1, the semiconductor package 109a with solder balls or paste 107a may be bonded to semiconductor panel 109b with solder flux or paste 107b. In an aspect, the proper alignment of the semiconductor packages 109a on the panel 109b may be maintained with the proper alignment of the solder balls 107a with the solder flux 107b.

In an aspect, the thermocompression bonding process may include the plurality of semiconductor packages 109a with attached solder balls 107a being positioned for bonding onto the semiconductor panel 109b with attached solder flux 107b.

In an aspect, the compression and heating surface of the bond head 102 is configured for heating and reflowing of solder flux 107b between the semiconductor panel 109b and the semiconductor package 109a for the semiconductor package 109a to be bonded to the semiconductor panel 109b.

In an aspect, the bonding stage 103 may include a heating element. The heating element may be on the surface of the bonding stage 103. The heating element may assist in the heating and reflowing of solder flux 107b between the semiconductor panel 109b and the semiconductor package 109a.

In an aspect, the solder ball 107a between the semiconductor panel 109b and the semiconductor package 109a may have a bump pitch of less than 50 μm.

In an aspect, the semiconductor package assembly 110 may have a square or rectangular shape panel 109b having a size of 500×500 mm or greater. It should be understood that a thermocompression bonding tool 100 will be configured with a bond head 102 and a bond stage 103 having form factors that permit the thermocompression bonding of such panels.

In an exemplary thermocompression bonding process, a semiconductor package 109a may be heated up quickly (e.g., up to 200° C./s) to above solder melting temperature (>230° C.) in order to reflow solders and form joints between a semiconductor chip and a semiconductor panel 109b. The bond stage 103 which hold the semiconductor package 109a in place, may experience fast heating and/or cooling cycles throughout this process.

If non low CTE material such as common bond stage materials, like tooling steel, Al alloy, Alumina, and Invar 36, which have low to medium CTE (3-20 ppm/K) at elevated temperatures (>200° C.) are used, the bond stage may locally expand and warp during heating/cooling cycles, which lead to variations in CGH control and further impact the yield.

Due to the temperature gradient and CTE of the bond stage material, local expansion is not uniform throughout the bondstage as the center location of the bond stage may expand more than edge locations of the bond stage, which may lead to over compression and solder bump bridging (SBB) risks for units that are bonded at center location. In some cases, it may result in semiconductor die pull from the panel.

In an exemplary thermomechanical models and experiments have been used to test the effectiveness of ultra-low CTE material to reduce and minimize bondstage local expansion in fast heating/cooling TCB cycles. When ultra-low CTE materials are used, the local expansion was able to be reduced ˜90% down to 4-5 μm using an ultra-low CTE ceramic vs. 30-50 μm using tooling steel under equivalent thermal conditions.

Further experimental efforts also confirmed and agreed with the modeling results, showing much greater local expansion magnitude and expansion variation (˜44%), as well as higher expansion rate (˜18.5 times higher) on the S7 tooling steel vs. the ultra-low CTE material. In the experiment, the magnitude of local expansion measured in the experiments is less than what predicted by the model. This is due to the less contact area and shorter heating time (˜2 s) that were used in the experiments. Nonetheless, the expansion rate measured at 320° C. reconfirmed the minimal stage expansion from the ultra-low CTE ceramic stage.

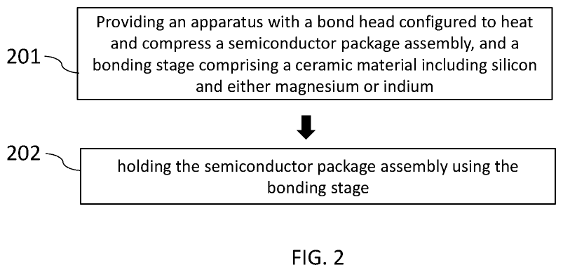

FIG. 2 shows a simplified flow diagram for an exemplary method according to an aspect of the present disclosure. In an aspect, the present method may be able to provide chip gap height control for production panel units. It should be understood that the present method may also be used for thermocompression bonding tools that are intended for wafer-level bonding.

The operation 201 may be directed to providing an apparatus with a bond head, and a bonding stage. The bond head may be configured to heat and compress a semiconductor package assembly. The bonding stage may include a ceramic material including silicon and either magnesium or indium.

The operation 202 may be directed to holding the semiconductor package assembly using the bonding stage.

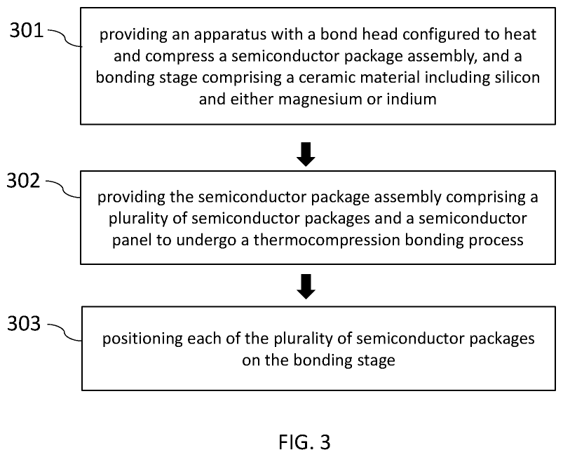

FIG. 3 shows a simplified flow diagram for another exemplary method according to an aspect of the present disclosure. In an aspect, the present method may be able to provide chip gap height control for production panel units. It should be understood that the present method may also be used for thermocompression bonding tools that are intended for wafer-level bonding.

The operation 301 may be directed to providing an apparatus with a bond head, and a bonding stage. The bond head may be configured to heat and compress a semiconductor package assembly. The bonding stage may include a ceramic material including silicon and either magnesium or indium.

The operation 302 may be directed to providing the semiconductor package assembly which includes a plurality of semiconductor packages and a semiconductor panel to undergo a thermocompression bonding process.

The operation 303 may be directed to positioning each of the plurality of semiconductor packages on the bonding stage.

It will be understood that any property described herein for a specific thermocompression bonding tool may also hold for any panel-level manufacturing tool not otherwise described herein. It will also be understood that any property described herein for a specific method may hold for any of the methods described herein. Furthermore, it will be understood that for any thermocompression bonding tool and the methods described herein, not necessarily all the components or operations described will be shown in the accompanying drawings or method, but only some (not all) components or operations may be disclosed.

To more readily understand and put into practical effect the present semiconductor carrier platforms and thermal stability layers, they will now be described by way of examples. For the sake of brevity, duplicate descriptions of features and properties may be omitted.

### Examples

Example 1 provides an apparatus including a bond head configured to heat and compress a semiconductor package assembly, and a bonding stage configured to hold the semiconductor package assembly, wherein the bonding stage includes a ceramic material including silicon and either magnesium or indium.

Example 2 may include the thermocompression bonding tool of example 1 and/or any other example disclosed herein, for which the semiconductor package assembly includes a plurality of semiconductor packages and a semiconductor panel.

Example 3 may include the thermocompression bonding tool of example 2 and/or any other example disclosed herein, for which the bond head and the bonding stage are configured to thermocompressively bond the plurality of semiconductor packages onto the semiconductor panel.

Example 4 may include the thermocompression bonding tool of example 3 and/or any other example disclosed herein, for which the bond head is configured to reflow solder flux between the semiconductor panel and the plurality of semiconductor packages.

Example 5 may include the thermocompression bonding tool of example 1 and/or any other example disclosed herein, for which the bonding stage includes a heating element.

Example 6 may include the thermocompression bonding tool of example 1 and/or any other example disclosed herein, for which the bonding stage includes a cordierite ceramic or a lithium aluminosilicate-glass ceramic.

Example 7 may include the thermocompression bonding tool of example 1 and/or any other example disclosed herein, for which the bonding stage includes a material having a coefficient of thermal expansion (CTE) of less than 1 ppm/K when heated up to 300° C.

Example 8 provides a method that provides an apparatus including a bond head configured to heat and compress a semiconductor package assembly and a bonding stage including a ceramic material including silicon and either magnesium or indium, holding the semiconductor package assembly using the bonding stage.

Example 9 may include the method of example 8 and/or any other example disclosed herein, for which the semiconductor package assembly includes a plurality of semiconductor packages and a semiconductor panel.

Example 10 may include the method of example 9 and/or any other example disclosed herein, further including thermocompressively bonding the plurality of semiconductor packages onto the semiconductor panel.

Example 11 may include the method of example 10 and/or any other example disclosed herein, further including using the bond head to reflow solder flux between the semiconductor panel and the plurality of semiconductor packages.

Example 12 may include the method of example 8 and/or any other example disclosed herein, in which the bonding stage includes a heating element.

Example 13 may include the method of example 8 and/or any other example disclosed herein, in which the bonding stage includes a cordierite ceramic or a lithium aluminosilicate-glass ceramic.

Example 14 may include the method of example 8 and/or any other example disclosed herein, in which the bonding stage includes a material having a coefficient of thermal expansion (CTE) of less than 1 ppm/K when heated up to 300° C.

Example 15 provides a method that provides an apparatus including a bond head configured to heat and compress a semiconductor package assembly and a bonding stage including a ceramic material including silicon and either magnesium or indium, providing the semiconductor package assembly including a plurality of semiconductor packages and a semiconductor panel to undergo a thermocompression bonding process, and positioning each of the plurality of semiconductor packages on the bonding stage.

Example 16 may include the method of example 15 and/or any other example disclosed herein, further including thermocompressively bonding the plurality of semiconductor packages onto the semiconductor panel.

Example 17 may include the method of example 16 and/or any other example disclosed herein, further including using the bond head to reflow solder flux between the semiconductor panel and the plurality of semiconductor packages.

Example 18 may include the method of example 15 and/or any other example disclosed herein, in which the bonding stage includes a heating element.

Example 19 may include the method of example 15 and/or any other example disclosed herein, in which the bonding stage includes a cordierite ceramic or a lithium aluminosilicate-glass ceramic.

Example 20 may include the method of example 15 and/or any other example disclosed herein, in which the bonding stage includes a material having a coefficient of thermal expansion (CTE) of less than 1 ppm/K when heated up to 300° C.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words: coupling without direct contact) may be provided.

The terms “and” and “or” herein may be understood to mean “and/or” as including either or both of two stated possibilities.

While the present disclosure has been particularly shown and described with reference to specific aspects, it should be understood by those skilled in the art that various changes in form and detail may be made therein without departing from the spirit and scope of the present disclosure as defined by the appended claims. The scope of the present disclosure is thus indicated by the appended claims and all changes which come within the meaning and range of equivalency of the claims are therefore intended to be embraced.

What is claimed is:

1. An apparatus, comprising:
a bond head configured to heat and compress a semiconductor package assembly; and
a bonding stage configured to hold the semiconductor package assembly, wherein the bonding stage comprises a ceramic material including silicon and either magnesium or indium.

2. The apparatus of claim 1, wherein the semiconductor package assembly comprises a plurality of semiconductor packages and a semiconductor panel.

3. The apparatus of claim 2, wherein the bond head and the bonding stage are configured to thermocompressively bond the plurality of semiconductor packages onto the semiconductor panel.

4. The apparatus of claim 3, wherein the bond head is configured to reflow solder flux between the semiconductor panel and the plurality of semiconductor packages.

5. The apparatus of claim 1, wherein the bonding stage comprises a heating element.

6. The apparatus of claim 1, wherein the bonding stage comprises a cordierite ceramic or a lithium aluminosilicate-glass ceramic.

7. The apparatus of claim 1, wherein the bonding stage comprises a material having a coefficient of thermal expansion (CTE) of less than 1 ppm/K when heated up to 300° C.

8. A method comprising:
providing an apparatus, the apparatus comprising a bond head configured to heat and compress a semiconductor package assembly and a bonding stage comprising a ceramic material including silicon and either magnesium or indium; and
holding the semiconductor package assembly using the bonding stage.

9. The method of claim 8, wherein the semiconductor package assembly comprises a plurality of semiconductor packages and a semiconductor panel.

10. The method of claim 9, further comprising:
thermocompressively bonding the plurality of semiconductor packages onto the semiconductor panel.

11. The method of claim 10, further comprising:
using the bond head to reflow solder flux between the semiconductor panel and the plurality of semiconductor packages.

12. The method of claim 8, wherein the bonding stage comprises a heating element.

13. The method of claim 8, wherein the bonding stage comprises a cordierite ceramic or a lithium aluminosilicate-glass ceramic.

14. The method of claim 8, wherein the bonding stage comprises a material having a coefficient of thermal expansion (CTE) of less than 1 ppm/K when heated up to 300° C.

15. A method comprising:
providing an apparatus, the apparatus comprising a bond head configured to heat and compress a semiconductor package assembly and a bonding stage comprising a ceramic material including silicon and either magnesium or indium;
providing the semiconductor package assembly comprising a plurality of semiconductor packages and a semiconductor panel to undergo a thermocompression bonding process; and
positioning each of the plurality of semiconductor packages on the bonding stage.

16. The method of claim 15, further comprising:
thermocompressively bonding the plurality of semiconductor packages onto the semiconductor panel.

17. The method of claim 16, further comprising:
using the bond head to reflow solder flux between the semiconductor panel and the plurality of semiconductor packages.

18. The method of claim 15 wherein the bonding stage comprises a heating element.

19. The method of claim 15, wherein the bonding stage comprises a cordierite ceramic or a lithium aluminosilicate-glass ceramic.

20. The method of claim 15, wherein the bonding stage comprises a material having a coefficient of thermal expansion (CTE) of less than 1 ppm/K when heated up to 300° C.
